(19) United States
(12) Patent Application Publication
(10) Pub. No.: US 2023/0294274 A1
(43) Pub. Date: Sep. 21, 2023

(54) THETA ROBOT WITH PRELOADED DRIVE SYSTEM

(71) Applicant: Service Support Specialties, Inc., Montville, NJ (US)

(72) Inventors: Gary Hillman, Livingston, NJ (US); Matthew Hoffer, Hackensack, NJ (US); Rodrigo Nogueira, Montclair, NJ (US)

(21) Appl. No.: 18/118,401

(22) Filed: Mar. 7, 2023

Related U.S. Application Data
(60) Provisional application No. 63/320,745, filed on Mar. 17, 2022.

(51) Int. Cl. B25J 9/10; B25J 11/00; B25J 9/04

(52) U.S. Cl. CPC B25J 9/1045; B25J 11/0095; B25J 9/042; H01L 21/6838

(57) ABSTRACT

A theta robot with integrated preload system in one embodiment includes a cable-operated drive mechanism including a rotatable pulley drum, motor drive operably coupled to the drum by drive cable, and follower piston cylinder operably coupled to the drum by a follower cable. The piston cylinder may be under vacuum and operably applies a tensile load and resistance on the pulley drum via the follower cable which eliminates clearance between meshed driving and driven components of the drive mechanism. When the motor drive feeds out drive cable, the pulley drum rotates in a first rotational direction, and when the motor drive retracts drive cable, the pulley drum rotates in an opposite second rotational direction. The vacuum piston cylinder operates to keep the drive cable in a taut condition when the motor drive feeds out the drive cable. The theta robot has broad applicability to numerous workpiece fabrication processes including semiconductors.

### CROSS-REFERENCE TO RELATED APPLICATION

The present application claims the benefit of priority to U.S. Provisional Application No. 63/320,745 filed Mar. 17, 2022; which is incorporated herein by reference in its entirety.

### BACKGROUND OF THE INVENTION

The present invention relates to workpiece handling system such as those used in semiconductor foundries or other applications, and more particularly to a preload system for rotatable robotic drive mechanisms.

Fabrication and manufacturing operations carried out on a workpiece require manipulation of the workpiece. In one industry, as a non-limiting example, the workpiece in the form of a semiconductor substrate or wafer on which semiconductor devices are built requires movement into various positions during the fabrication process. From start to finish in the process, the wafer is loaded into and unloaded from different semiconductor device transport devices which hold multiple wafers (e.g., cassettes) to shuttle the wafers between equipment and different parts of the foundry, and fabrication tools which variously deposit layers of materials on the wafer, etch and surface smooth the deposited materials, form trenches and via holes for formation of the inter-layer electrical conductors, test the devices on the wafers, and perform other functions. The mechanized robots which temporarily hold and maneuver the wafers must therefore be able to articulate and assume various positions and orientations to accomplish the inter-equipment transfer and transport of the wafers.

Angular rotation or translation of the workpiece such as a wafer, referred to as “theta” or “R-theta” rotational motion or translation about a rotational theta axis, may be performed with a “theta” robot. The theta robot includes a motor drive mechanism which imparts rotational motion to a workpiece holding device such as an end effector configured to support and move the wafer. When moving workpieces from place to place in the manufacture of semiconductors, the wafer's position must be well known. This is especially so for those operations involving the rotation of the wafer, owing to unwanted vibration when the wafer is not centered with respect to the axis of rotation as an example. The only way to deliver a wafer having a known position is to know the position of the mechanism accomplishing such motion. When a motion is accomplished with no additional mechanism but directly from the prime mover, then it is possible to resolve the position precisely, though the prime movers to do so tend to be very expensive. However in most cases, it is necessary to drive the axis through a mechanism involving the use of gears or similar mechanisms. The clearance normally associated with the use of gears creates a condition in which, owing to that clearance, the position of the work piece (i.e. wafer) is not known precisely. While there exists gear arrangements that have no clearance, said to “run in interference,” they tend to be both expensive and inefficient.

Improvements in rotational theta drive mechanisms are desired which allow the precise position of the workpiece such as a semiconductor wafer to be known at all times.

### SUMMARY OF THE INVENTION

A motor-operated theta robot drive mechanism is disclosed which essentially eliminates completely the clearance as between the driven and the driving components of the drive mechanism for rotating the workpiece holding device such as without limitation a wafer holding device about the theta axis. The drive mechanism includes a preload device which is configured to apply a preload to the meshed driven and driving components of the theta drive mechanism.

In one non-limiting embodiment, the theta drive mechanism may be used in conjunction with and coupled to a linear translation robot such as an R translation robot with a workpiece holding device or end effector. The workpiece may be a semiconductor wafer in one non-limiting embodiment. The R translation robot is configured to linearly translate the wafer in a known manner. With this combination, the theta robot drive mechanism rotates the R translation robot and wafer therewith about the theta axis, while the motor drive of the R translation robot linearly translates the wafer in opposing linear directions for insertion into and removal from various semiconductor fabrication tools or transport devices.

In one embodiment, the theta drive mechanism of the theta robot may be cable operated including without limitation an electric theta motor operably coupled to a pulley drum by a drive cable, and the preload device which applies the preload to the meshed drive components of the drive mechanism. In one embodiment, the preload device may be without limitation a vacuum follower piston cylinder operably coupled to the drum by a follower cable. The follower piston cylinder comprises a cylinder fluidly coupled to a vacuum source so that the piston cylinder is under a constant predetermined vacuum (negative pressure). The vacuum pulls the piston of the piston cylinder away from the drum such that the piston applies a constant tensile load and resistance on the pulley drum via the follower cable. This eliminates the clearance between the driven and the driving components of the drive mechanism.

In operation, when the theta motor lets or feeds out the drive cable to rotate the pulley drum in a first rotational direction, the tensile force or resistance applied on the drum by the vacuum operated follower piston cylinder keeps the drive cable taut to smoothly rotate the drum and R translation robot coupled thereto. Conversely, when the theta motor retracts the drive cable to rotate the pulley drum in an opposite second rotational direction, the motor is pulling against the tensile load on the drum imparted by the follower piston cylinder. Accordingly, each rotational motion of the pulley drum has an applied preload to eliminate the drive component clearance.

It bears noting that embodiments of the theta drive mechanism with preload system disclosed herein does not provide continuous rotation of the wafer holding device greater than 360 degrees. This is provided by other semiconductor fabrication tools for other purposes such as spin coating materials onto the wafer, etc. Instead, the present theta drive mechanism may be configured to provide rotation up to but not exceeding 360 degrees in some embodiments, and less than 360 degrees in one non-limiting embodiment shown herein. As one example, the theta drive mechanism of the theta robot may have a rotational or angular range of motion vis-à-vis the pulley drum of up to 270 degrees. When coupled to the foregoing R translation robot, the theta drive mechanism provides the ability to rotate the wafer, and linearly insert the wafer into and retrieve the wafer from various tools and apparatuses in the semiconductor foundry.

In one aspect, a theta robot with preload system comprises: a support frame; a pulley drum supported by the frame and rotatable about a vertical theta axis; a motor drive coupled to the pulley drum by a drive cable, the motor drive configured to feed out and retract the drive cable; and a follower piston cylinder coupled to the pulley drum by a follower cable, the follower piston cylinder operable to apply a tensile load on the pulley drum; wherein when the motor drive feeds out the drive cable, the pulley drum is rotated in a first rotational direction, and when the motor drive retracts the drive cable, the pulley drum is rotated in an opposite second rotational direction. The follower piston cylinder is operable to keep the drive cable in a taut condition when the motor drive feeds out the drive cable. The follower piston cylinder is under a vacuum which applies the tensile load on the pulley drum which is constant when the pulley drum is rotated in either the first or second rotational directions. In one embodiment, the pulley drum may rotate 270 degrees between a first angular position and a second angular position.

According to another aspect, a method for operating a theta robot comprises: providing a theta drive mechanism comprising a pulley drum, a motor drive including a drive cable coupled to the pulley drum, and a follower piston cylinder coupled to a follower cable coupled to the pulley drum; applying a vacuum to the piston cylinder which in turn creates a tensile load on the pulley drum and corresponding resistance to rotation in a first rotational direction; rotating the motor drive in a first direction; the motor drive winding out cable from the pulley drum by overcoming the resistance on pulley drum created by the piston cylinder; and rotating the pulley drum about a theta axis from a first angular position to a second angular position. The pulley drum may rotate 270 degrees between the first angular position and the second angular position in some embodiments. The method may further comprise rotating the motor drive in a second direction, feeding out the drive cable, and winding the drive cable fed out by the motor drive back onto the pulley drum. The rotating the pulley drum step may include rotating a linear translation robot coupled to the pulley drum concurrently from the first angular position to the second angular position.

According to another aspect, a pulley drum for a theta robot drive mechanism comprises: a substantially cylindrical body comprising a plurality of stacked pulley drum segments comprising: a lower segment configured for direct or indirect support by a support frame; an intermediate segment detachably coupled to the lower segment; an upper segment detachably coupled to the intermediate segment; a circumferentially-extending upper cable groove formed between the upper and intermediate segments, the upper cable groove configured for engaging a first operating cable; a circumferentially-extending lower cable groove formed between the lower and intermediate segments, the lower cable groove configured for engaging a second operating cable; the first operating cable anchored to the body of the pulley drum in the upper cable groove; and the second operating cable anchored to the body of the pulley drum in the lower cable groove; wherein the pulley drum is rotatable about a theta axis.

According to another aspect, a method for assembling a pulley drum for a theta robot drive mechanism comprises: providing a plurality of pulley drum segments including an upper segment, intermediate segment, and a lower segment; coupling the upper, intermediate, and lower segments together in stacked relationship to collectively define a body of the pulley drum; inserting a first end of a first operating cable of the drive mechanism in an anchoring portion of a first cable groove formed by the upper segment; anchoring the first operating cable in the anchoring portion of the first cable groove; inserting a first end of a second operating cable of the drive mechanism in an anchoring portion of a second cable groove formed by the intermediate segment; and anchoring the second operating cable in the anchoring portion of the second cable groove; wherein the coupled pulley drum is rotatable about an axis of rotation.

In all of the above aspects noted, the pulley drum may be configured for coupling to a workpiece holding device and the workpiece may be a semiconductor wafer in one non-limiting embodiment.

### BRIEF DESCRIPTION OF THE DRAWINGS

The present invention will become more fully understood from the detailed description and the accompanying drawings, wherein:

FIG. 1 is a first perspective view of a theta robot with pulley-operated theta drive mechanism in accordance with an embodiment of the present invention;

FIG. 2 is a second perspective view thereof;

FIG. 3 is first perspective view of the theta robot with external side panels removed to reveal the robot internal support frame and drive mechanism components;

FIG. 4 is a second perspective view thereof;

FIG. 5 is a third perspective view thereof;

FIG. 6 is a top view of the theta robot;

FIG. 7 is a bottom view of the theta robot;

FIG. 8 is a side elevation view of a theta robot;

FIG. 9 is a second side elevation view thereof;

FIG. 10 is a third side elevation view thereof;

FIG. 11A is a fourth side elevation view thereof showing the theta drive mechanism in a first operating position;

FIG. 11B is a fifth side elevation view thereof showing the theta drive mechanism in a second operating position;

FIG. 12 is a transverse cross sectional view of the drive mechanism taken from FIG. 8;

FIG. 13 is an enlarged perspective view of the top of the theta robot showing the pulley drum assembly and related cable guide components;

FIG. 14 is a top perspective view of the theta robot;

FIG. 15 is an enlarged view of the pulley drum;

FIG. 16 is a bottom view thereof;

FIG. 17 is a top view thereof;

FIG. 18 is an exploded side view thereof showing individual pulley drum segments;

FIG. 19 is a bottom exploded perspective view thereof;

FIG. 20 is a top exploded perspective view thereof;

FIG. 21 is a side view of the upper portion of the theta robot showing the pulley drum and drive components;

FIG. 22 is an enlarged side view of the top portion thereof;

FIG. 23 is a side view of the theta robot coupled to a linear translation robot which is rotatable by the theta robot;

FIG. 24 is a top view thereof; and

FIG. 25 is a perspective view thereof showing a semiconductor substrate or wafer held by end effectors of the linear translation robot.

All drawings are schematic and not necessarily to scale. Components numbered and appearing in one figure but appearing un-numbered in other figures are the same components unless expressly noted otherwise. Any reference herein to a figure by a whole figure number which may appear in multiple figures bearing the same whole number prefix but with different alphabetical suffixes shall be construed as a general reference to all of those figures unless expressly noted otherwise.

### DETAILED DESCRIPTION OF THE INVENTION

The features and benefits of the invention are illustrated and described herein by reference to example (“exemplary”) embodiments. This description of example embodiments is intended to be read in connection with the accompanying drawings, which are to be considered part of the entire written description. Accordingly, the disclosure expressly should not be limited to such embodiments illustrating some possible non-limiting combination of features that may exist alone or in other combinations of features.

In the description of embodiments disclosed herein, any reference to direction or orientation is merely intended for convenience of description and is not intended in any way to limit the scope of the present invention. Relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected,” “coupled,” and “interconnected,” refer to a relationship wherein structures are secured or attached to one another either directly or indirectly through intervening structures, as well as both movable or rigid attachments or relationships, unless expressly described otherwise.

As used throughout, any ranges disclosed herein are used as shorthand for describing each and every value that is within the range. Any value within the range can be selected as the terminus of the range.

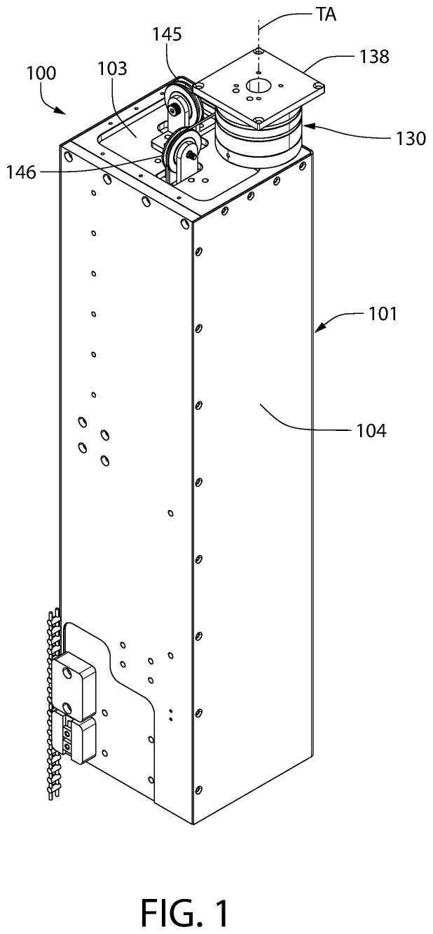

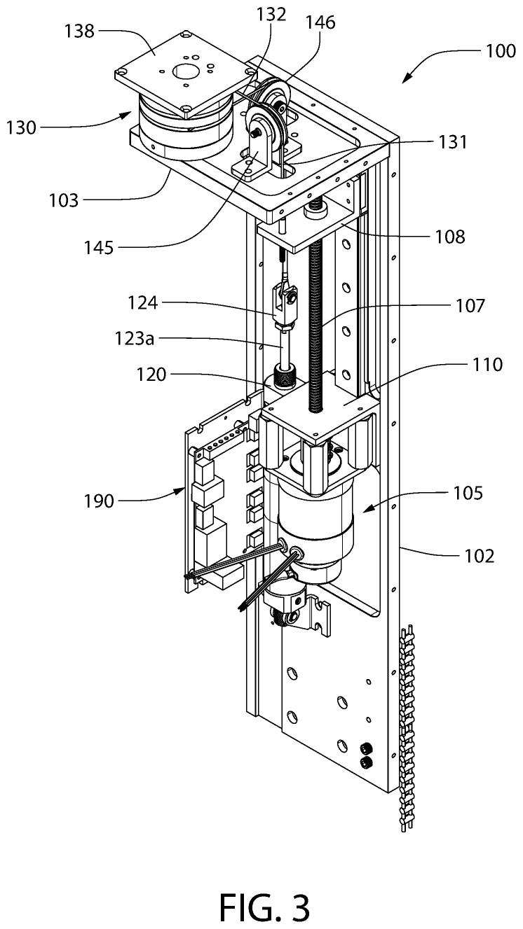

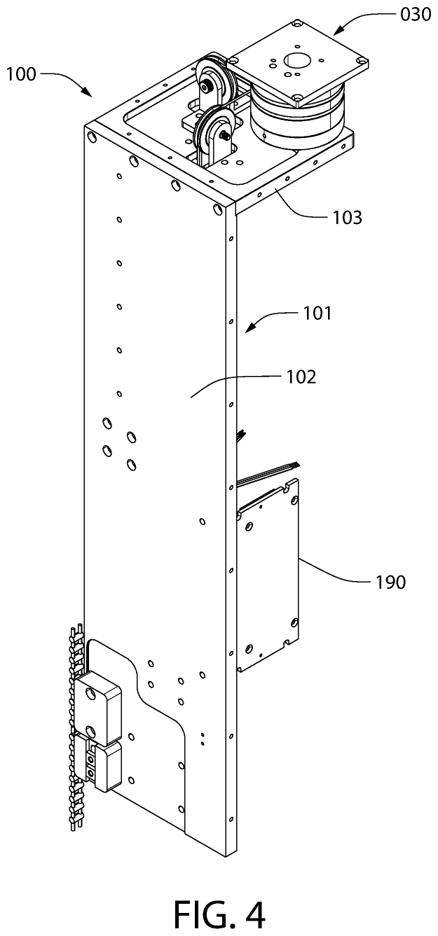

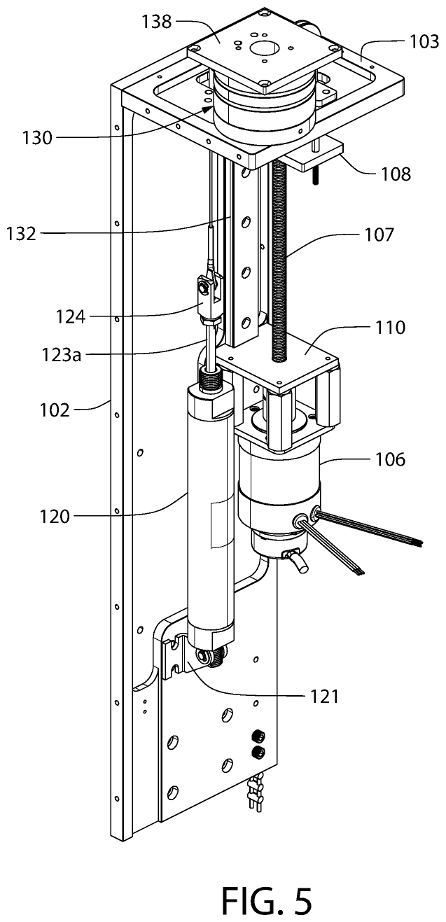

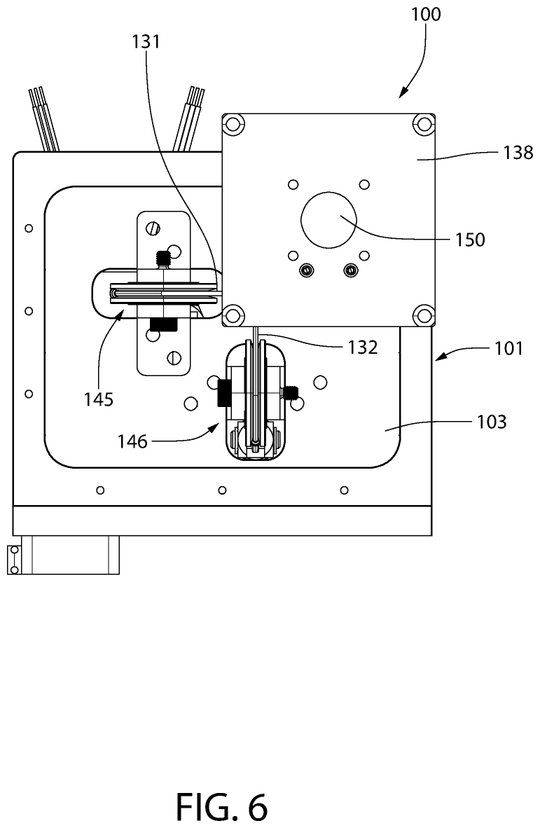

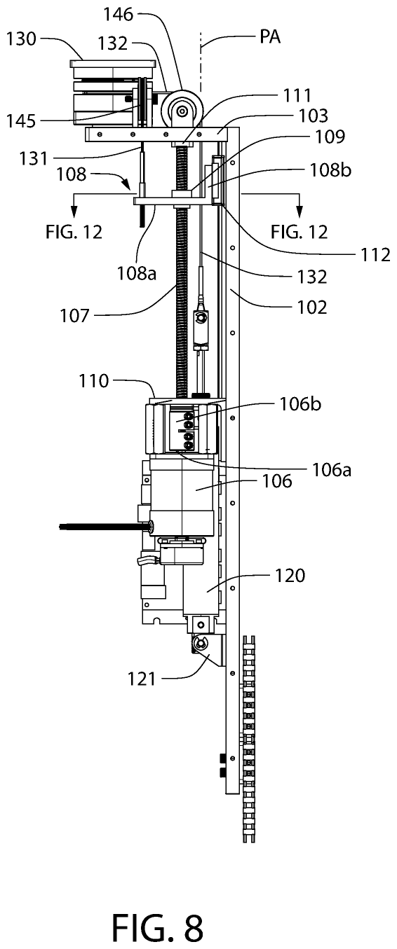

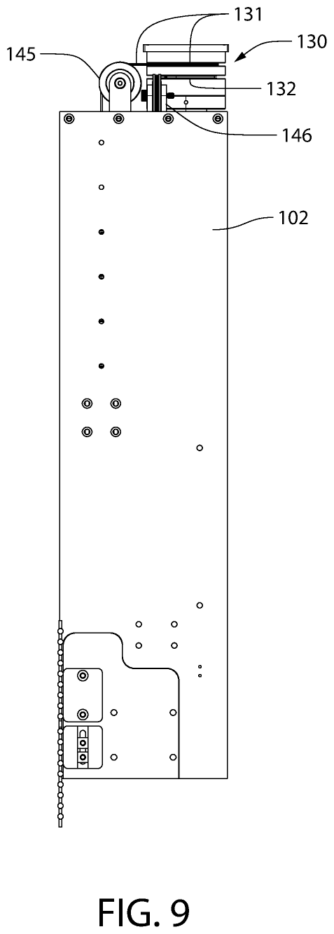

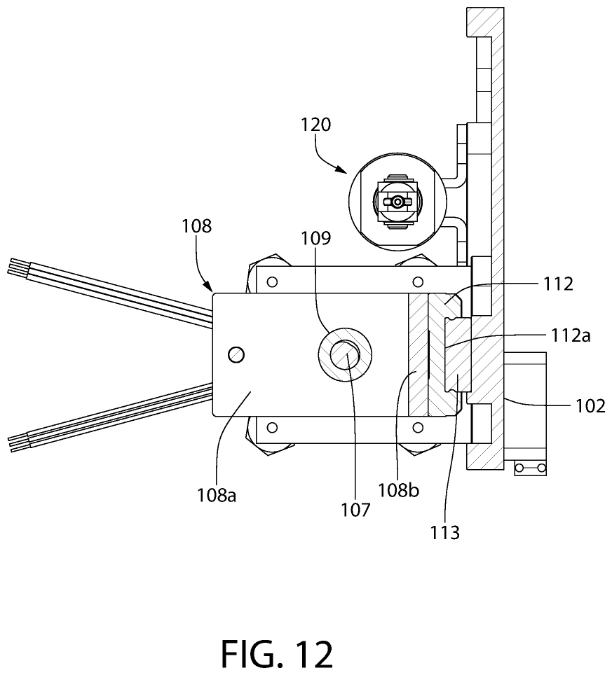

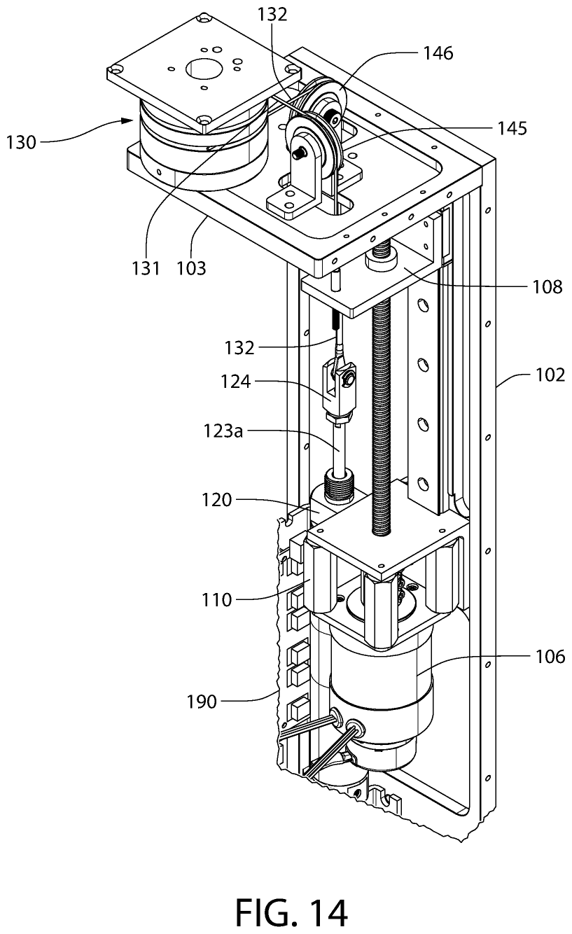

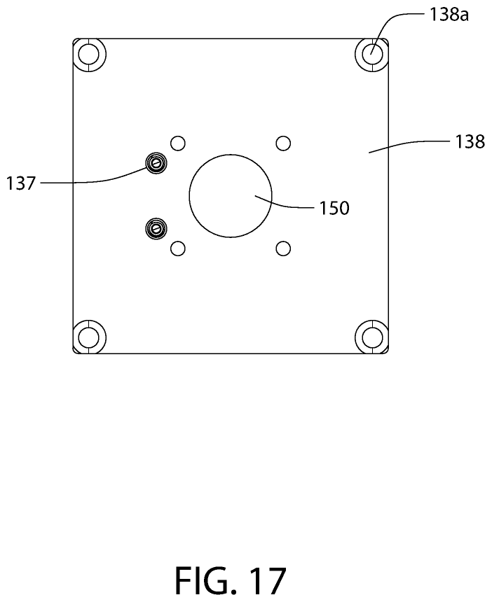

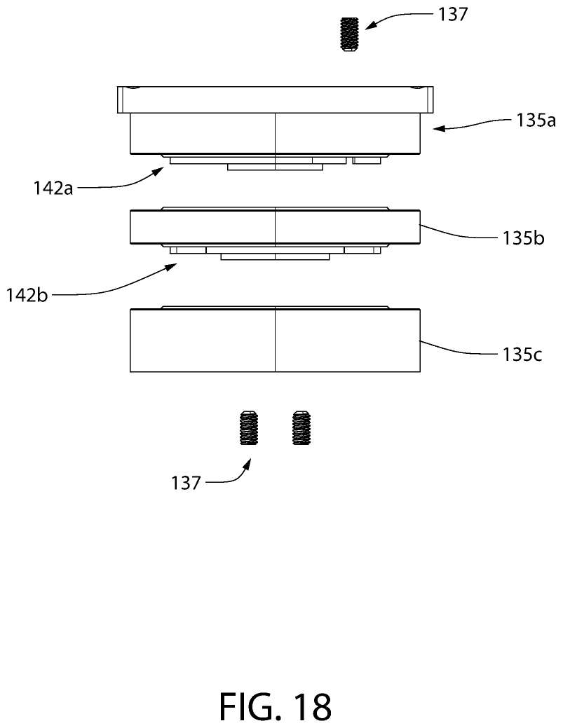

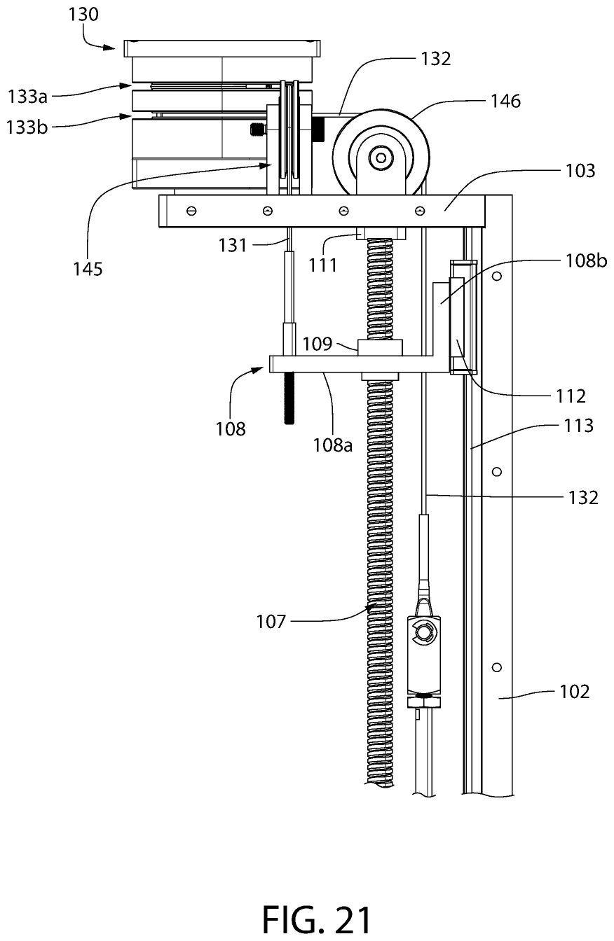

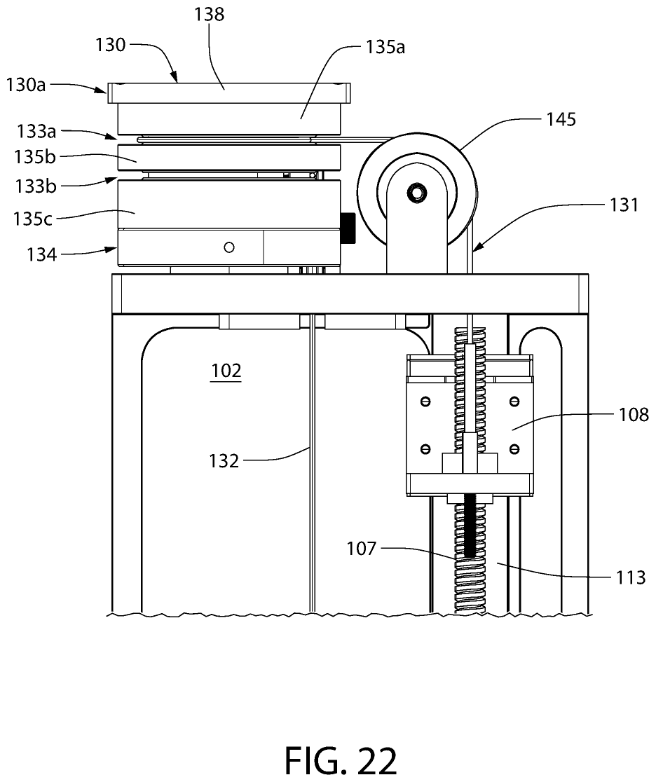

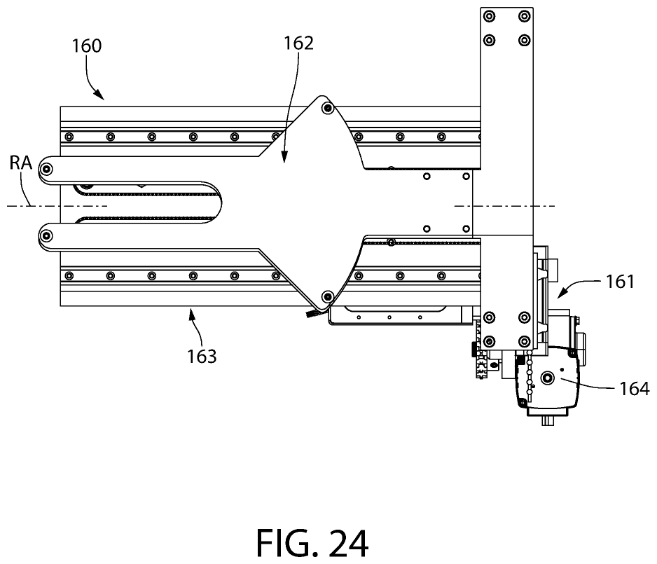

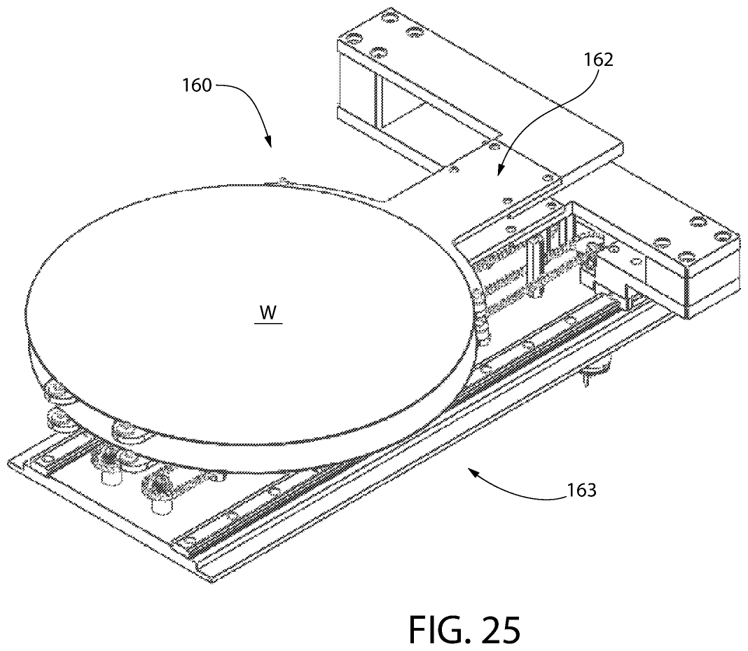

FIGS. 1-25 depict one embodiment of a robot according to the present disclosure, such as without limitation a theta robot 100. The theta robot comprises a theta drive mechanism with integrated preload system for rotating a semiconductor substrate or wafer handling device configured in turn to hold and translate the substrate or wafer. The wafer handling device in one non-limiting embodiment may be a linear translation robot such as an R translation robot 160 further described herein.

For purposes of description and not limitation, it bears noting that the terms substrate or wafer may be used interchangeably herein and includes those formed of any type of materials in need of handling including without limitation crystalline silicon wafers, glass substrates, fiber optic substrates, fused quartz, fused silica, epitaxial silicon, or others.

Furthermore, it will be appreciated that the theta robot disclosed herein is not limited to use with any particular type of workpiece or substrate such as a semiconductor wafer for example, or to any particular type of workpiece or wafer holding device. The present theta robot has broad applicability and may be used for the handling of any type of workpiece or article in a fabrication process requiring rotational manipulation and explicitly includes those applications completely unrelated to semiconductor device production. Accordingly, the theta drive mechanism is not limited in applicability to semiconductor fabrication processes alone, which is disclosed herein as one possible use.

Referring with initial general reference to FIGS. 1-25, theta robot 100 may include a support housing or frame 101 which supports the pulley-operated theta drive mechanism 105 and its components. The support frame may be made of structural metal components shown for rigidity and stability in one embodiment. In one configuration, support frame 101 may include at least one vertical back support plate 102 and a top support plate 103 fixedly coupled thereto in a rigid manner. Top support plate 103 may be cantilevered from and oriented perpendicularly to the back support plate 102 in one embodiment and positioned at the top of the back support plate as shown. The back support plate 102 is vertically elongated with greater height than width. Other arrangements, positioned, and orientations of the support plates however may be used.

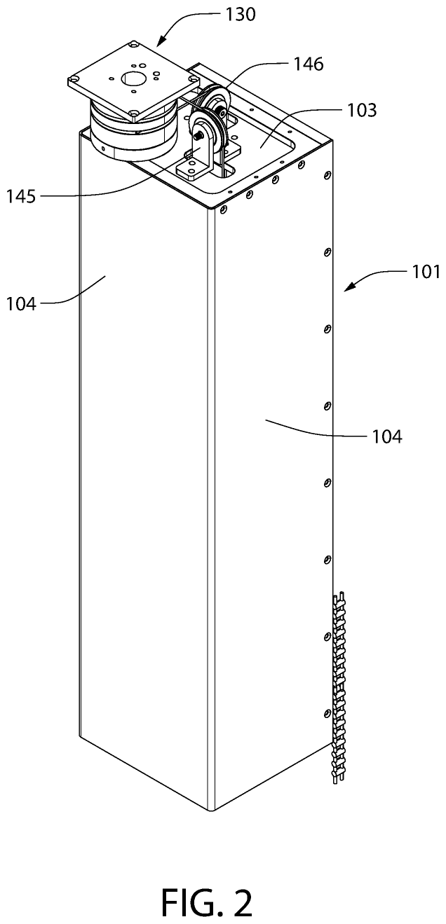

The support frame 101 may include a plurality of removable side panels 104 which may substantially enclose and protect the theta drive mechanism 105 and electronic programmable controller 190 on all sides (see, e.g., FIGS. 1 and 2). The term “substantially” as used here connotes that there may be certain open areas in the panels to provide access to the drive mechanism or allow wiring, air/vacuum flow conduits, or other types of connections to be made to the drive mechanism components. However, a majority of the side surface area of the support frame 101 may be enclosed by the side panels 104 in one embodiment.

The theta drive mechanism 105 of theta robot 100 in one embodiment includes a pulley-operated motor drive which generally comprises an electric bi-directional/reversible theta drive motor 106 mounted to support frame 101 (e.g., vertical back support plate 102), a vertically elongated drive screw 107 coupled to the motor and selectively rotatable via operation of the motor in opposing rotational directions, a vertically moveable drive cable slide bracket 108 rotatably engaged with the drive screw via a threaded coupling 109 on the bracket, a pulley drum 130, and vacuum follower piston cylinder 120. Each component and operation of the theta drive mechanism 105 are described in further detail below.

Any suitable commercially-available constant or variable speed reversible electric motor may be used for the motor drive. The motor 106 may be fixedly attached to the vertical back support plate 102 in a stationary manner by motor bracket 110. Motor 106 may be vertically oriented and spaced distally below top support plate 103 of the theta robot support frame 101 in one embodiment as shown. This vertical spacing is sufficient to provide room for the drive screw 107 coupled to the top of the motor. Motor 106 therefore has a rotating drive shaft 106a coupled to the bottom end of drive screw 107 via a conventional shaft coupler 106b and is operable to rotate the screw in opposing rotational directions by reversing the rotation of the motor.

The drive screw 107 may similarly be vertically oriented and is elongated in structure as shown in the illustrated embodiment. Drive screw 107 extends vertically between top support plate 103 and motor 106. Any suitable type of commercially-available power drive screw may be used, such as for example without limitation a lead screw with suitable thread configuration (e.g., acme, stub acme, worm, etc.) or ball screw. The top end of drive screw 107 is rotatably coupled to top support plate 103 of the support frame via a rotary bearing 111. The bearing laterally supports the top of the screw but allows free rotation in either direction. Any suitable commercially-available rotary type bearing may be used for this purpose.

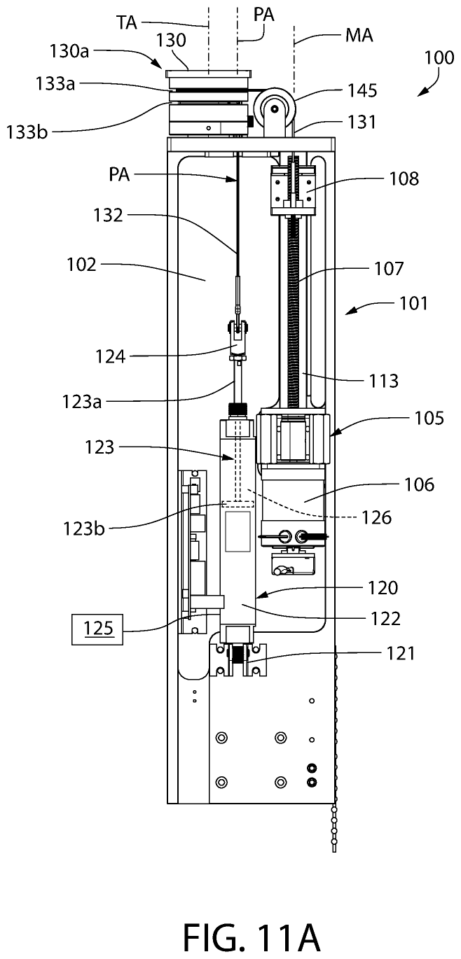

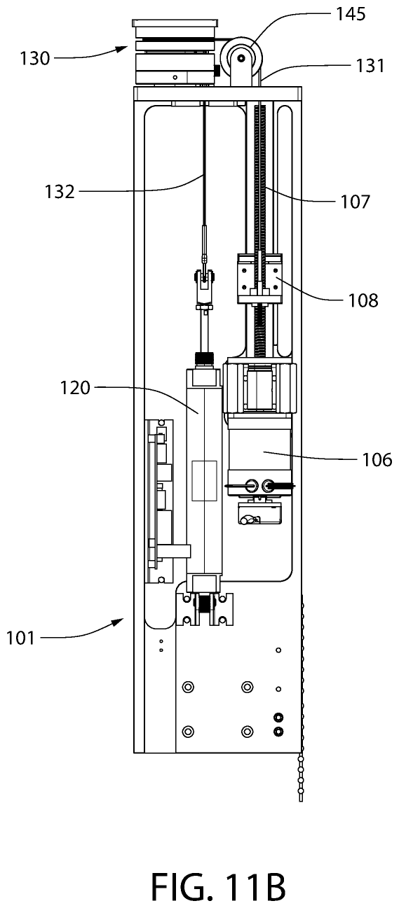

Slide bracket 108 is linearly movable vertically upwards and downwards along the drive screw 107 via rotation of the screw in opposing rotational directions. Accordingly, slide bracket 108 is moveable between an uppermost position (see, e.g., FIG. 11A) and a lowermost position (see, e.g., FIG. 11B), and plurality of intermediate positions therebetween as needed. The slide bracket may have a metallic body formed of a suitable metal such as steel, aluminum, or others. In one embodiment, the slide bracket body may be L-shaped comprising a horizontal section 108a and vertical section 108b rigidly coupled thereto. Threaded drive coupling 109 may be fixedly mounted to horizontal section 108a in one embodiment to engage the drive screw 107 as shown. Accordingly, the coupling and drive screw preferably have complementary configured threads which are mutually engageable. Drive coupling 109 converted rotational motion of drive screw 107 to linear motion of drive cable slide bracket 108 in opposing directions upwards and downwards along the screw.

Vertical section 108b of slide bracket 108 may include a guide member 112 defining an outwardly open guide channel 112a which horizontally faces vertical back support plate 102. Guide channel 112a is open at the top and bottom to slideably receive and engage a mating elongated vertical guide rail 113 disposed or formed on support plate 102. The guide rail stabilizes and laterally supports the slide bracket 108 as it translates upwards and downwards on drive screw 107 along the back support plate. This guided motion of the bracket ensures smooth operation of the theta drive mechanism by providing lateral stability to the bracket in a manner which resists twisting or rotation of the bracket about the drive screw as the bracket moves. Accordingly, slide bracket 108 remains square to vertical back support plate 102 as it translates vertically up and down drive screw 107.

Motor 106 and concomitantly drive screw 107 defines a vertical motor axis MA for reference. Slide bracket 108 is therefore vertically movable in opposing directions along and parallel to motor axis.

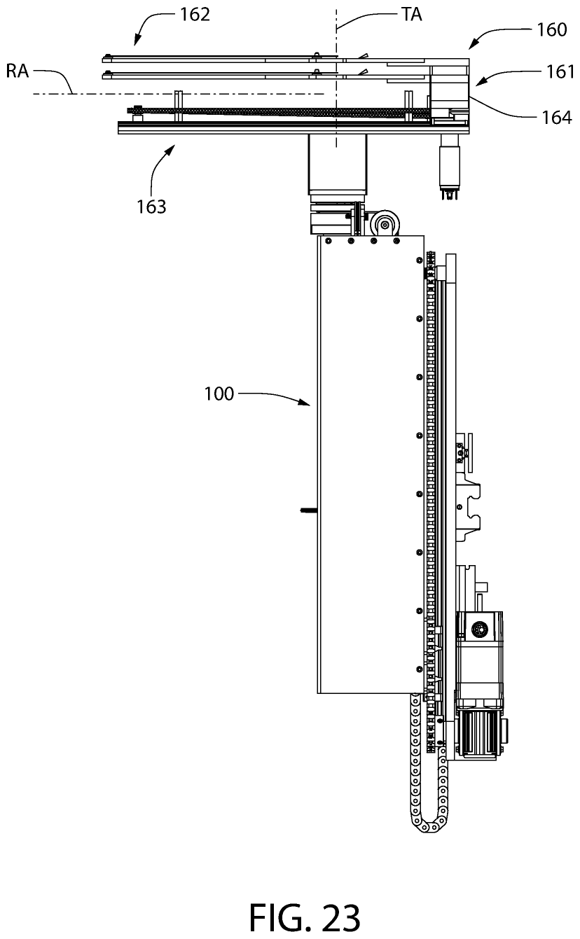

Pulley drum 130 is mounted at the top of the theta robot 100 above the drive motor 106 to interface with a linear translation robot, such as without limitation R translation robot 160 shown in FIGS. 23-25. The pulley drum imparts rotational motion to the robot via the theta drive mechanism 105 as further described herein. Referring back generally to FIGS. 1-22 as applicable, in one embodiment the pulley drum 130 may be rotatably supported by top support plate 103 of the robot support frame 101 via a rotary support bearing 134 mounted to the support plate. Suitable commercially-available rotary support bearings may be used. Pulley drum 130 defines a vertical rotational theta axis TA and is rotatable about its axis in opposing rotational directions. Theta axis TA is parallel to motor axis MA (see, e.g., FIGS. 11A-B).

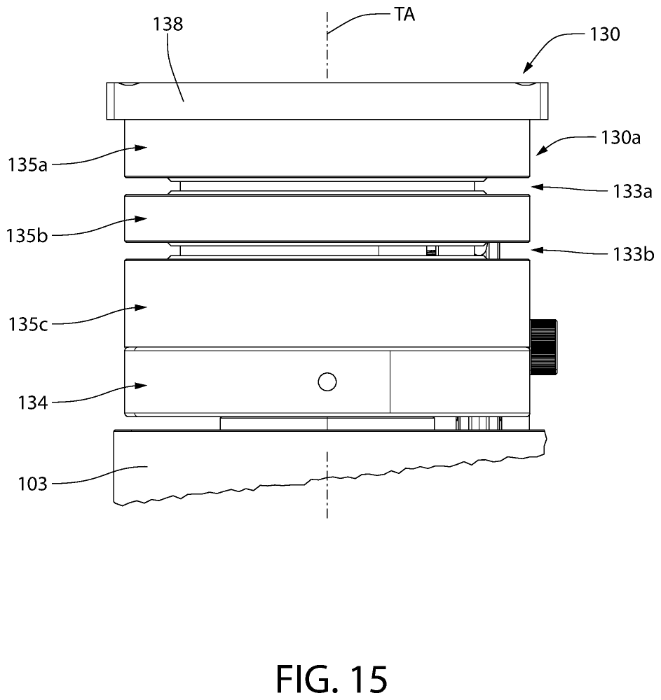

FIGS. 15-20 show one non-limiting construction of pulley drum 130 in isolation and greater detail. The pulley drum 130 may have a generally cylindrical body 130a which is configured to receive and operably engage at least two operating cables which impart motion and load on the drum. The operating cables in one embodiment includes a motor drive cable 131 operably coupled to the motor-drive screw 106/107 assembly, and a follower cable 132 operably coupled to the follower piston cylinder 120. Any suitable type of metallic tension cables such as twisted/braided steel cables in one non-limiting example may be used which are structured to withstand tensile loading without significant elongation which might induce a lag in pulley drum response to the motor drive.

Pulley drum 130 in one embodiment includes a circumferentially-extending and annular upper cable groove 133a and lower cable groove 133b. Each groove is recessed into the exterior of pulley drum body and may extend a fully 360 degrees around the drum. The grooves are parallel to each other and the horizontal top surface of the top support plate 103. Accordingly, the grooves 133a, 133b are horizontally oriented and perpendicular to the rotational theta axis TA. In one embodiment, the drive cable 131 may engage upper cable groove 133a and follower cable 132 lower cable groove 133b. In other embodiments, this order may be reversed.

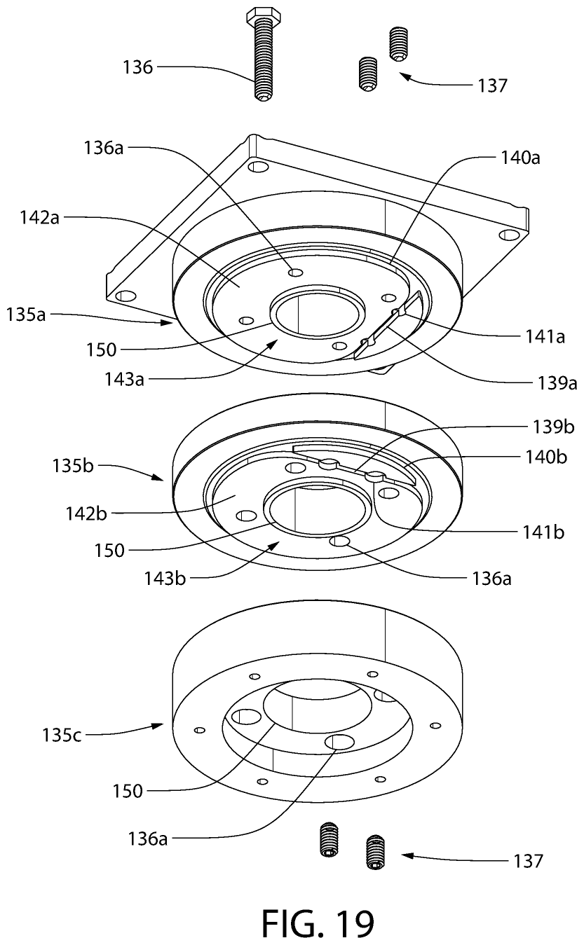

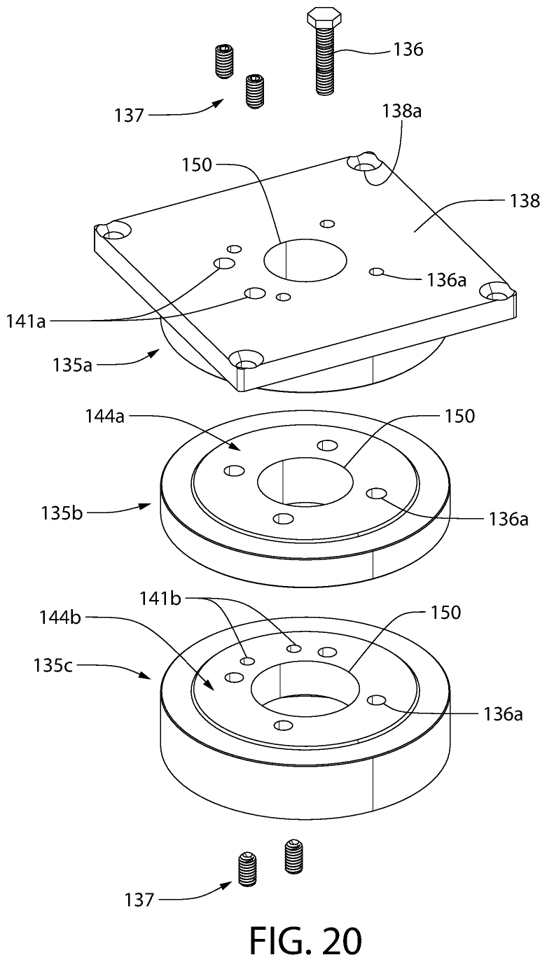

The body 130a of pulley drum 130 may have a monolithic unitary structure in one embodiment. In other embodiments as depicted herein, however, the pulley drum body 130a may have a segmented structure including an upper segment 135a, intermediate segment 135b, and lower segment 135c fixedly coupled to rotary support bearing 134. Each segment is fixedly coupled to the next adjacent pulley segment or segments. In one construction, the segments may be stacked and detachably coupled together such as via a plurality of threaded coupling fasteners 136 inserted through fastener holes 136a in the segments. Note only a representative single fastener 136 is shown in FIGS. 19 and 20 for clarity of depiction. Fasteners 136 having a length which pass through all of the segments 135a-c may be used, or shorter length fasteners which separately couple the upper to intermediate segment, and lower segment to intermediate segment. Each pulley segment collectively forms the entire pulley body 130a when coupled and assembled together.

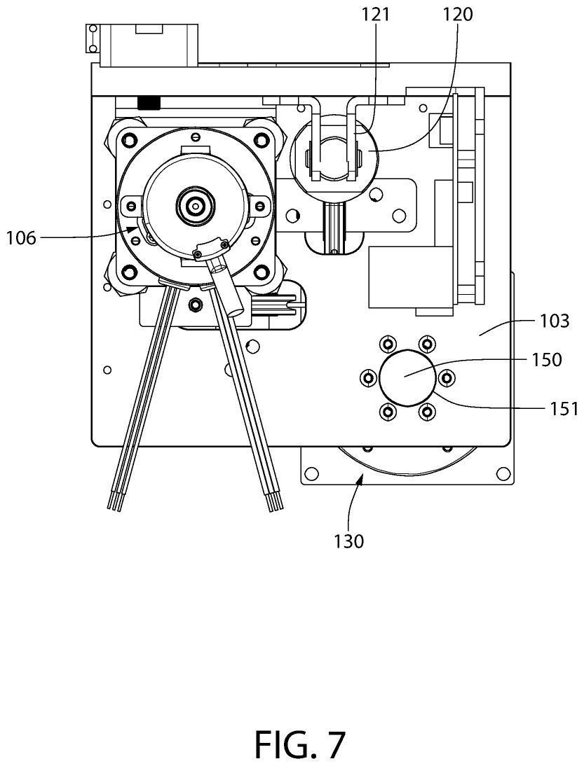

Pulley drum segments 135a, 135b, and 135c may each have a generally circular cylindrical shape in one embodiment. In one embodiment, each segment may further comprise an annular shape defining a central opening 150 configured for passing electrical and control wires therethrough for the linear R translation robot 160 from below the top support plate 103 of the support frame which has a cooperating opening 151 (see, e.g., FIG. 7). The wires can enter the R translation robot in a non-exposed manner therefore for protection and convenience as opposed to external wire routings to the robot. When the drum segments are coupled together, a common central opening 150 extends from top to bottom of pulley drum 130.

In one embodiment with reference to FIGS. 15 and 18-20, the pulley drum upper cable groove 133a and lower cable groove 133b may be formed by circular/cylindrical spacer protrusions. The pulley drum upper segment 135a includes spacer protrusion 142a projecting downwards therefrom. The pulley drum intermediate segment 135b similarly includes spacer protrusion 142b projecting downwards therefrom. Each spacer protrusions 142a, 142b defines a downward facing flat surface 143a, 143b which abuttingly engages a corresponding upward facing flat surface 144a, 144b formed on the intermediate segment 135b and lower segment 135c, respectively. The spacer protrusions 142a, 142b are each spaced radially inwards from the cylindrical sides of the pulley drum upper segment 135a and intermediate segment 135b. When the pulley drum segments 135a-c are assembled together, the spacer protrusions 142a, 142b each define an outwardly open annular recess which correspondingly define the upper cable groove 133a and lower cable groove 133b.

A rectilinear (e.g., square or rectangular) or other polygonal or non-polygonal shaped metallic mounting plate 138 may be coupled to pulley drum upper segment 135a. Mounting plate 138 is configured for interfacing with and coupling linear R translation robot 160 thereto (see, e.g., bolt holes 138a in one non-limiting embodiment). The R translation robot is therefore supported entirely by the pulley drum 130 and theta robot 100 in one non-limiting embodiment. In some constructions, the mounting plate may be integrally formed with the upper pulley segment as an integral monolithic unitary part thereof instead of being a separate structural part fixedly coupled to the upper segment 135a. Either construction may be used.

It bears noting that if the mounting plate 138 is integrally formed as part of the pulley drum upper segment 135a, the body 130a of pulley drum 130 may instead by considered to have a “substantially” cylindrical body which simply connotes that at least a majority of the body of the drum is cylindrical in shape except for the mounting plate.

The segmented embodiment of pulley drum 130 advantageously allows the drive cable 131 and follower cable 132 to be easily anchored to the drum in a manner which does not interfere with the operation of the drum including winding and unwinding of the cables as the drum is rotated in opposing directions via the motor 106 and follower piston cylinder 120, as further described herein. This ensures smooth operation of the drum 130 and robot.

Accordingly, in one non-limiting assembly method, the pulley drum segments 135a-c may be coupled together in vertically stacked abutting relationship as previously described herein using the coupling fasteners 136. The drive and follower cables 131, 132 may be fixedly anchored to the pulley segments. For example, as shown in FIGS. 15-20, a top end of the drive cable 131 may be fixedly anchored to one pulley segment such as upper segment 135a by inserting the top end and adjoining end portion of the cable in an anchoring portion 139a of upper groove 133a formed in the upper segment. The anchoring portion 139a communicates and is contiguous with the circumferential portion 140a of upper cable groove 133a and may comprise a straight or linear chord of the circle created by the annular circumferential portion. Anchoring portion 139a may intersect and be in communication with the circumferential portion 140a at two locations at opposite open ends of the linear anchoring portion (best shown in FIG. 19). In other embodiments, the anchoring portion 139a may intersect circumferential portion 140a at only one open end of the anchoring portion which may extend only partially from one side of the circumferential portion to the other. A pair of threaded anchoring fasteners 137 (e.g., set screws, etc.) are received in threaded anchoring holes 141a in upper segment 135a and the holes intersect the groove anchoring portion 139a. The anchoring fasteners engage and lock the top end portion of drive cable 131 into the linear anchoring portion of upper cable groove 133a by compressing the cable against the underlying intermediate pulley drum segment 135b. The drive cable 131 emerges from one end of the anchoring portion 139a of upper cable groove 133a and enters the contiguous circumferential portion 140a of the upper cable groove for exterior routing around the pulley drum 130 and outwards therefrom for coupling to the drive cable slide bracket 108 below.

A similar cable anchoring arrangement may be used for follower cable 132. Without fully repeating the foregoing description, briefly lower cable groove 133b on pulley intermediate segment 135b may include a similarly configured straight/linear anchoring portion 139b in which top end of the follower cable 132 is inserted, The end portion of the follower cable is then fixedly anchored by threaded anchoring fasteners 137 received through threaded anchoring holes 141b formed through drum lower segment 135c which intersect anchoring portion 139b formed on the bottom of the intermediate drum segment 135b. Threaded anchoring fasteners 137 extend upwards through lower segment 135c and compress the cable 132 into the linear anchoring portion 139b and against the above intermediate pulley drum segment 135b. The follower cable 132 emerges from the anchoring portion 139ba of lower cable groove 133b and enters the contiguous circumferential portion 140b of the lower upper cable groove for exterior routing around the pulley drum and outwards therefrom for coupling to follower piston cylinder 120 below.

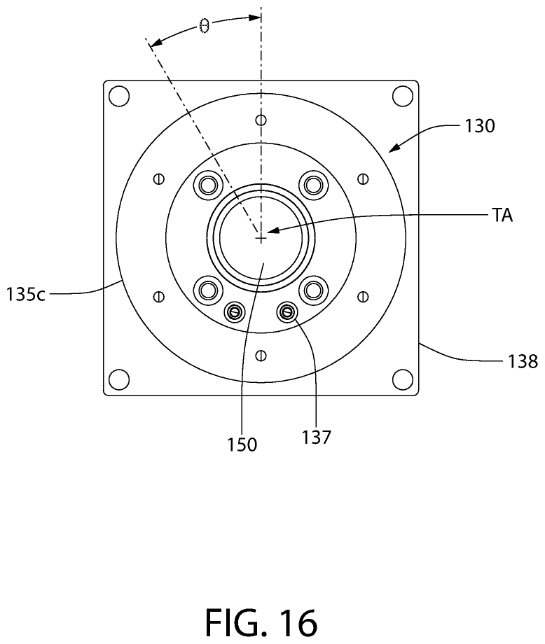

It bears noting that the drive and follower cables 131, 132 may each be inserted into their respective anchoring portions 139a, 139b, and then anchored in place with anchoring fasteners 137 in grooves 133a, 133b after the pulley segments 135a-c are assembled and coupled together with coupling fasteners 136. As shown in FIGS. 16-20, the threaded anchoring holes 141a, 141b formed in pulley segments 135a, 135b are accessible from above and below the assembled pulley drum 130. The lower threaded anchoring holes 141b may have portions which are formed in both pulley drum lower segment 135c and intermediate segment 135b (see, e.g., FIGS. 19-20).

Other suitable methods to fixedly anchor the top ends of the drive and follower cables 131, 132 to their respective pulley drum segments 135a, 135b may be used.

The method or process for assembling the foregoing segmented pulley drum 130 of a theta robot drive mechanism 105 may be summarized in one non-limiting embodiment as generally comprising: providing the plurality of pulley drum segments including upper segment 135a, intermediate segment 135b, and a lower segment 135c; coupling the upper, intermediate, and lower segments together in vertically stacked relationship to collectively define a body 130a of the pulley drum; inserting a first end of a first operating cable (e.g., drive cable 131) of the drive mechanism in an anchoring portion of a first cable groove formed by the upper segment; anchoring the first operating cable in the anchoring portion of the first cable groove; inserting a first end of a second operating cable (e.g., follower cable 132) of the drive mechanism in an anchoring portion of a second cable groove formed by the intermediate segment; and anchoring the second operating cable in the anchoring portion of the second cable groove; wherein the coupled pulley drum is rotatable about an axis of rotation.

Embodiments of the foregoing method/process for assembling pulley drum 130 may further include the following. The first anchoring step comprises inserting at least one anchoring fastener through the upper segment to engage the first operating cable in the anchoring portion of the first cable groove after at least the upper and intermediate segments are coupled together. The second anchoring step comprises inserting at least one anchoring fastener through the lower segment to engage the second operating cable in the anchoring portion of the second cable groove after the lower and intermediate segments are coupled together. The coupling step includes abuttingly engaging a downward facing flat surface of the upper segment with a mating upward facing flat surface of the intermediate segment, and abuttingly engaging a downward facing flat surface of the intermediate segment with a mating upward facing flat surface of the lower segment. The coupling step forms the first and second cable grooves. The first cable groove is defined by a circular spacer protrusion extending downwards from upper segment which defines the downward facing flat surface thereof, and the second cable groove is defined by a circular spacer protrusion extending downwards from intermediate segment which defines the downward facing flat surface thereof. The first and second cable grooves each include an outwardly open circumferentially-extending circumferential portion extending circumferentially around an entirety of the pulley drum, the circumferential portions each being contiguous respectively with the first and second anchoring portions of the first and second cable grooves. The first and second anchoring portions of the first and second cable grooves are each linear and intersect their respective circumferential portions. The first cable groove is spaced apart from the second cable groove along the rotational axis. The first and second cable grooves are configured to engage first and second operating cables respectively which are operable to rotate the pulley drum around the rotational axis. Each of the segments have an annular shape and define a common central opening extending along the rotational axis when the segments are coupled together. The upper segment comprises a mounting plate configured for coupling a linear translation robot thereto, and the lower segment is configured for coupling to a support frame of a theta robot configured to rotate the pulley drum.

Other aspects of the theta robot 100 cable-operated drive mechanism 105 is further described below.

With continuing general reference now to FIGS. 1-22 as applicable, bottom end of drive cable 131 is fixedly coupled to drive cable slide bracket 108. This couples the motor drive to the pulley drum 130. In one embodiment, drive cable 131 may be coupled to horizontal section 108a of the bracket. The drive cable therefore is unwound from and wound onto pulley drum 130 via downward or upward movement of the slide bracket on drive screw 107 as motor 106 rotates the screw in opposing directions, respectively. The motor drive therefore alternatingly feeds out or retracts the cable 131 by rotating the drive screw in opposing directions.

In turn, follower piston cylinder 120 is operably coupled to the pulley drum 130 by follower cable 132. The follower piston cylinder is operable to apply a tensile load or resistance on the pulley drum which counteracts the load applied to the drum on the other hand by operation of the motor 106 when it unwinds drive cable 131 from the pulley drum. The motor must therefore have sufficient torque to rotate drive screw 107 and overcome this tensile load. Conversely, when the motor rotates drive screw 107 in the opposite direction to feed out drive cable, the tensile load keeps the drive cable in a taut condition. Operation of the theta drive mechanism 105 is further describe herein.

In one embodiment, the vacuum follower piston cylinder 120 may be fixedly mounted to a portion of support frame 101 such as vertical back support plate 102 by piston cylinder bracket 121. Piston cylinder 120 may be mounted below top support plate 103 of robot support frame 101 and pulley drum 130. The follower piston cylinder generally includes a sealed outer cylinder 122 defining the pressure retention boundary, and piston 123 comprising piston rod 123a and diametrically enlarged piston head 123b coupled thereto and slideably movable inside the cylinder. The piston head is sealed to the interior of the cylinder by suitable piston seal rings (not shown but known in the art). Piston rod 123a extends through the top end or head of the cylinder and is projectible outwards and retractable into the cylinder. The bottom end of the follower cable 132 is coupled to the exposed part of the piston rod which projects outwards from the cylinder 122 by any suitable coupling method. In one embodiment, a clevis 124 threadably coupled to the outside end of piston rod 123a may be used for this purpose as shown. Any suitable commercially-available pneumatic piston cylinder may be used for vacuum follower piston cylinder 120 capable of withstanding an internal vacuum or negative pressure.

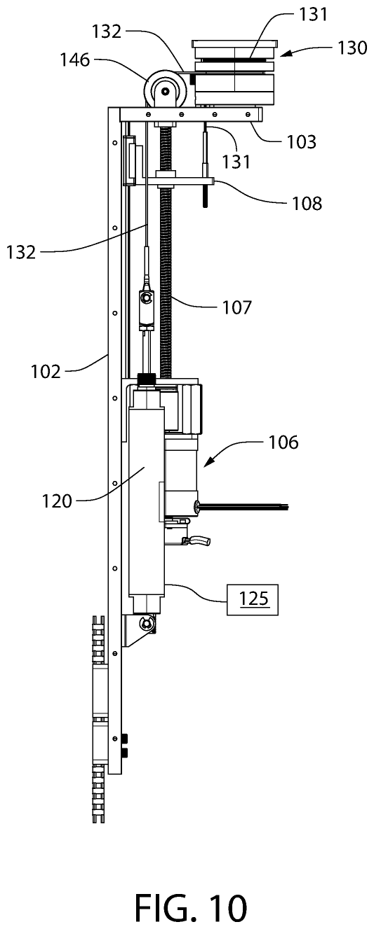

The interior of the cylinder 122 below the piston head 123b is fluidly coupled to a vacuum source 125. This draws the piston rod 123a downwards which creates the tensile force on follower cable 132 and in turn creates a fixed tensile load or resistance on the pulley drum 130. Any suitable vacuum source 125 (represented schematically in FIG. 10) may be used, such as but not limited to a vacuum pump, vacuum system of the theta robot coupled to a vacuum pump, or other available source of constant vacuum or negative pressure. In one non-limiting example, a vacuum operable to create a 12 pound constant tensile load may be applied to the follower cable and pulley drum. Other tensile loads may be used as appropriate.

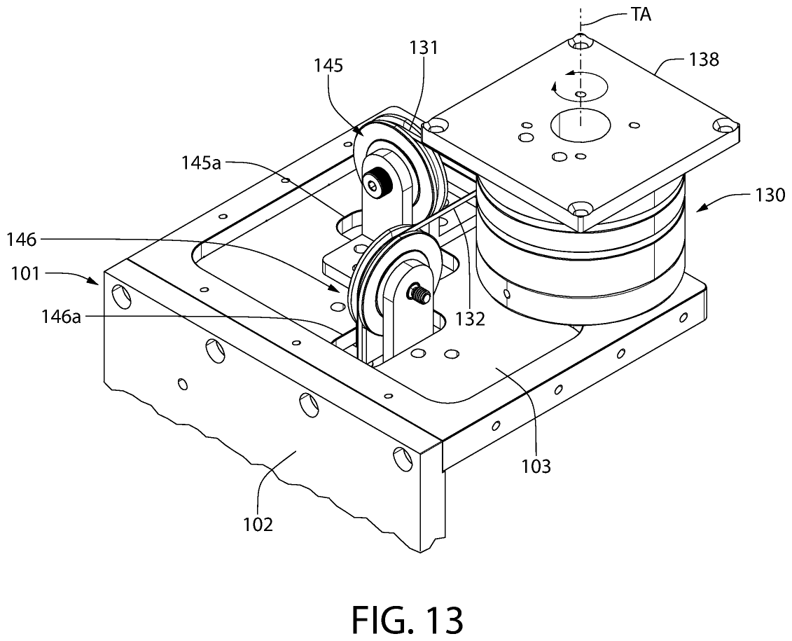

Because both motor 106 and vacuum follow piston cylinder 120 are mounted below pulley drum 130, a pair of pulley wheels 145, 146 may be provided to change direction of the drive and follower cables 131, 132 from vertical below top support plate 103 to horizontal above the plate in order to couple the cables to the drum. The pulley wheels may be fixedly mounted on top of the top support plate 103 adjacent to pulley drum 130 (see, e.g., FIG. 13). Pulley wheel 145 engages and movably guides the drive cable 131 into the upper cable groove 133a of the pulley drum. Pulley wheel 146 engages and movably guides the follower cable 132 into the lower cable groove 133b of the drum. Each pulley wheel has an associated opening 145a, 146a through top support plate 103 which allows cables 131, 132 to pass vertically through the support plate as shown.

FIGS. 23-25 depict one non-limiting representative embodiment of a linear R translation robot 160 usable with theta robot 100 and mountable to pulley drum 130 for rotation about the theta axis TA. Robot 160 generally includes a frame 163, motor-operated R drive mechanism 161 comprising electric R drive motor 164, end effector 162 configured to hold and support a semiconductor substrate or wafer W. The R translation robot frame 163 may be detachably coupled to mounting plate 138 of pulley drum 130 via any suitable method, such as via threaded fasteners or other. Drive mechanism is operable to translate the end effector and wafer in opposing horizontal linear motions back and forth along the R axis RA. Axis RA is oriented perpendicularly to theta axis TA. Accordingly, the theta drive mechanism 105 rotates the R translation robot 160 by a preselected angle θ (see, e.g., FIG. 16) about theta axis TA to a theta angular position while the R drive mechanism 161 linearly translates the wafer at the angular position selected. As previously described herein, theta drive mechanism 105 may be configured and operable to provide rotation of the R translation robot 160 and wafer W up to but not exceeding 360 degrees in some embodiments, and less than 360 degrees in one non-limiting embodiment shown herein. In one representative example, the theta drive mechanism 105 of the theta robot 100 may be operable to rotate pulley drum 130 and concomitantly R translation robot 160 through an angle θ up to 270 degrees. It bears noting that other angles θ of rotation between and including θ degrees and 360 degrees may be used depending on the needs and layout of the semiconductor fabrication tools for maneuvering the wafer.

Although the theta robot 100 with theta drive mechanism 105 comprising the integrated preload system is shown and described as imparting theta rotational motion to an R translation robot 160, it will be appreciated by those skilled in the art that the theta robot may be coupled to any other type of machine or apparatus in the semiconductor. Furthermore, the theta robot may be used in other types of application unrelated to the semiconductor industry where robotic fabrication techniques and machines are being employed. Accordingly, the present invention has broad applicability across many different types of applications and industries.

Operation of the theta drive mechanism 105 of theta robot 100 will now be briefly described with general reference to FIGS. 1-25. Additional specific reference to certain figures will be made where helpful.

FIG. 11A shows the theta robot 100 and associated drive mechanism 105 in a first operating position. The drive cable slide bracket 108 is in an upper position proximate to but not necessarily contacting the underside of the top support plate 103 of robot support frame 101 to prevent damage to the components. Concomitantly, the pulley drum 130 and linear R translation robot 160 coupled thereto are each in a first angular or rotational position about the theta axis TA corresponding to and associated with the upper position of the drive cable slide bracket 108. The preload system disclosed herein comprising the vacuum piston cylinder 120 eliminates clearance between the drive component of the theta drive mechanism to ensure that the first angular/rotational position is precisely known.

Using the upper position of drive cable slide bracket 108 in FIG. 11A as one possible starting point for operation of the theta robot 100 for convenience of description and reference, theta drive mechanism 105 may then be actuated by starting and running the drive motor 106 in a first rotational direction. This turns the drive screw 107 in a corresponding first rotational direction. The rotating drive screw translates the rotational motion of the screw and motor into linear motion of the slide bracket 108. In this case, the slide bracket progresses vertically downwards along the drive screw to a second lower position shown in FIG. 11B. This is a second operational position of the theta robot 100 and associated drive mechanism 105. As slide bracket 108 moves downwards, it pulls the drive cable 131 affixed thereto correspondingly downwards with it causing the pulley drum 130 to rotate in turn. The drive cable unwinds from pulley drum 130 in the process and rotates the drum and R translation robot 160 coupled thereto into a second angular or rotational position different than the initial first angular or rotational position associated with drive cable slide bracket 108 when in its upper position. In one non-limiting example, the drum 130 may be rotated by an angle θ of 270 degrees about theta axis TA to reach the second rotational position. Angles less than or greater than 270 degrees up to 360 degrees may be used in other embodiments as previously described herein.

It bears noting that theta drive motor 106 is pulling drive cable 131 out from the pulley drum 130 against the resistance to rotation created by the tensile force or load imparted to the drum by the vacuum piston cylinder 120 through follower cable 132. Accordingly, once the pulley drum and R translation robot 160 reaches their shared second angular or rotational position and the theta drive motor 106 is then abruptly stopped, the preload applied by piston cylinder 120 which advantageously eliminates the clearance between the driven and driving components of the theta drive mechanism 105 ensures that a precise second angular/rotational position is known.

To return the drive cable slide bracket 108 to its initial upper position, theta drive mechanism 105 may then be re-actuated by starting and running the drive motor 106 in an opposite second rotational direction. This turns the drive screw 107 in a corresponding second rotational direction opposite the first rotational direction. In this case, the slide bracket progresses vertically back upwards along the drive screw to its initial first upper position. As slide bracket 108 moves upwards, the pulley drum 130 under the tensile load or force created by piston cylinder 120 winds drive cable 131 back onto the drum in unison with the theta drive mechanism 105 feeding out drive cable. Thought of another way, the piston cylinder 120 acts to create a constant tensile load or force on pulley drum 130 via follower cable 132 which pulls on the drum and tries to rotate it in a rotational direction opposite to the rotational direction of the drum when drive mechanism is retracting and unwinding drive cable 131 from the drum to lower drive cable slide bracket 108 as described above. The tensile load or force created by piston cylinder 120 on pulley drum 130 advantageously keeps the drive cable taut as the drive mechanism and its motor feeds out drive cable, and acts concurrently to eliminate clearance between the drive components so that the drum and wafer position are precisely known as previously described herein. The drum rotates back in the second rotational direction to wind drive cable 131 up and travels back through an angle θ of 270 degrees about theta axis TA to return to the first angular or rotational position.

Numerous variations of the above method or process may be used and the invention is not limited to the steps or sequence enumerated.

In some embodiments, operation of the theta robot 100 and theta drive mechanism 105 which implements the foregoing method may be controlled by an automated control system including a programmable robotic system controller 190. Controller 190 is operably coupled and communicably linked to components of the drive mechanism previously described herein such as drive motor 106 and others as appropriate to fully automate the system. The controller 190 may be operably coupled to other components and devices, including sensors configured to measure motion, pressure/vacuum such as associated with operation of the follower piston cylinder 120, and others as appropriate. The control system may be configured for bidirectional communication with all of the foregoing components, devices, and sensors, and to interface with external control systems.

System controller 190 may include one or more processors, non-transitory tangible computer or machine readable medium such as memory, user interface, programmable input/output peripherals, and all other necessary electronic appurtenances and devices normally associated with a fully functional processor-based controller and control system. Any suitable commercially-available programmable controller may be used.

While the foregoing description and drawings represent exemplary (“example”) embodiments of the present invention, it will be understood that various additions, modifications and substitutions may be made therein without departing from the spirit and scope and range of equivalents of the accompanying claims. In particular, it will be clear to those skilled in the art that the present invention may be embodied in other forms, structures, arrangements, proportions, sizes, and with other elements, materials, and components, without departing from the spirit or essential characteristics thereof. In addition, numerous variations in the methods/processes as applicable described herein may be made without departing from the spirit of the invention. One skilled in the art will further appreciate that the invention may be used with many modifications of structure, arrangement, proportions, sizes, materials, and components and otherwise, used in the practice of the invention, which are particularly adapted to specific environments and operative requirements without departing from the principles of the present invention. The presently disclosed embodiments are therefore to be considered in all respects as illustrative and not restrictive, the scope of the invention being defined by the appended claims and equivalents thereof, and not limited to the foregoing description or embodiments. Rather, the appended claims should be construed broadly, to include other variants and embodiments of the invention, which may be made by those skilled in the art without departing from the scope and range of equivalents of the invention.

1. A theta robot with integrated preload system comprising:
a support frame;
a pulley drum supported by the frame and rotatable about a vertical theta axis;
a motor drive coupled to the pulley drum by a drive cable, the motor drive configured to feed out and retract the drive cable; and
a follower piston cylinder coupled to the pulley drum by a follower cable, the follower piston cylinder operable to apply a tensile load on the pulley drum;
wherein when the motor drive feeds out the drive cable, the pulley drum is rotated in a first rotational direction, and when the motor drive retracts the drive cable, the pulley drum is rotated in an opposite second rotational direction.

2. The theta robot according to claim 1, wherein the follower piston cylinder is operable to keep the drive cable in a taut condition when the motor drive feeds out the drive cable.

3. The theta robot according to claim 1, wherein the follower piston cylinder is under a vacuum which applies the tensile load on the pulley drum which is constant when the pulley drum is rotated in either the first or second rotational directions.

4. The theta robot according to claim 3, further comprising a vacuum source fluidly coupled to the follower piston cylinder which applies a constant vacuum to the piston cylinder which in turn creates a constant tensile load on the pulley drum.

5. The theta robot according to claim 2, wherein the motor drive comprises:
a bi-directional motor mounted to the frame;
a vertically elongated drive screw selectively rotatable by the motor in opposing rotational directions; and
a slide bracket rotatably engaged with the drive screw and a first end of the drive cable fixedly coupled to the slide bracket;
wherein rotating the drive screw in one direction moves the slide bracket upwards to feed out the drive cable, and rotating the drive screw in another direction moves the slide bracket downwards to retract the drive cable.

6. The theta robot according to claim 5, wherein the slide bracket includes a guide recess which slideably engages a vertical guide rail on the frame when the slide bracket moves upwards and downwards to prevent the slide bracket from twisting during motion.

7. The theta robot according to claim 5, wherein a second end of the drive cable is fixedly coupled to the pulley drum, a first end of the follower cable is coupled to follower piston cylinder, and a second end of the follower cable is fixedly coupled to the pulley drum.

8. The theta robot according to claim 5, wherein the motor and follower piston cylinder are fixedly mounted to the support frame in a stationary manner.

9. The theta robot according to claim 1, wherein the drive cable is received in a first circumferential cable groove on the pulley drum, and the follower cable is received in a second circumferential cable groove on the pulley drum, the first and second cable grooves being at different heights.

10. The theta robot according to claim 9, further comprising a first pulley wheel arranged to guide to drive cable from the motor drive into the first circumferential cable groove, and a second pulley wheel arranged to guide the follower cable from the follower piston cylinder into the second circumferential cable groove.

11. The theta robot according to claim 9, wherein the pulley drum has a cylindrical segmented body comprising a lower segment, an upper segment, and an intermediate segment coupled to and between the lower and upper segments.

12. The theta robot according to claim 10, wherein the upper, intermediate, and lower segments are detachably coupled together and top ends of the drive and follower cables are anchors between the segments by threaded fasteners.

13. The theta robot according to claim 10, wherein the lower, intermediate, and upper segments are annular in shape and collectively define a vertically-extending central through passage configured for routing electrical cables therethrough.

14. The theta robot according to claim 1, wherein the follower piston cylinder and motor drive are mounted to the support frame below the pulley drum which is mounted to a top plate of the support frame.

15. The theta robot according to claim 1, wherein the pulley drum is configured to coupling to a workpiece holding device.

16. The theta robot according to claim 15, wherein the workpiece holding device is a linear translation robot coupled to a top of the pulley drum and rotatable about the theta axis via the motor drive, the linear translation robot configured to hold and move the workpiece wafer in opposing linear directions.

17. The theta robot according to claim 15, wherein the workpiece is a semiconductor wafer.

18. A method for operating a theta robot comprising:
providing a theta drive mechanism comprising a pulley drum, a motor drive including a drive cable coupled to the pulley drum, and a follower piston cylinder coupled to a follower cable coupled to the pulley drum;
applying a vacuum to the piston cylinder which in turn creates a tensile load on the pulley drum and corresponding resistance to rotation in a first rotational direction;
rotating the motor drive in a first direction;
the motor drive winding out cable from the pulley drum by overcoming the resistance on pulley drum created by the piston cylinder; and
rotating the pulley drum about a theta axis from a first angular position to a second angular position.

19. The method according to claim 18, further comprising rotating the motor drive in a second direction, feeding out the drive cable, and winding the drive cable fed out by the motor drive back onto the pulley drum.

20. The method according to claim 19, further comprising rotating the pulley drum from the second angular position back to the first angular position.

21-47. (canceled)
